(19) United States
(12) Patent Application Publication
(10) Pub. No.: US 2002/0066110 A1
(43) Pub. Date: May 30, 2002

(54) Method and apparatus for preventing re-ranging and re-registration of cable modems during protection switching between active and spare cable interface cards in a cable modem termination system

(76) Inventors: Thomas J. Cloonan, Lisle, IL (US); Janusz Biegaj, Hinsdale, IL (US); Steven J. Krapp, Arlington Heights, IL (US); Jeffrey R. Shroda, Bolingbrook, IL (US); Daniel W. Hickey, Oswego, IL (US); Todd D. Kessler, Naperville, IL (US); Jeffrey J. Howe, West Chicago, IL (US); Alfred R. Zantow, Elgin, IL (US)

Correspondence Address: BANNER & WITCOFF, LTD., TEN SOUTH WACKER DRIVE, SUITE 3000, CHICAGO, IL, 60606, US

(21) Appl. No.: 09/725,704

(22) Filed: Nov. 29, 2000

(51) Int. Cl. H04N 7/173; H04L 1/22; H04B 1/74; H02H 3/05; H04L 1/00; H05K 10/00; H03K 19/003

(52) U.S. Cl. 725/111; 370/216; 714/11

(57) ABSTRACT

In a cable data system that includes a cable modem termination system or CMTS, high-reliability is accomplished by reducing the time required to switch over traffic from a failed circuit to a back up circuit. Fault recovery time to switch over to a spare circuit is reduced by copying the operational parameters used in each of the active circuits into a spare circuit such that upon the failure of an active circuit, the spare circuit needs only to be instructed which set of operational parameters for a particular failed circuit to use. Clock counters that are continuously incremented in active circuits can be copied into a newly installed circuit by copying into a local register for the newly installed circuit, a future value of a clock counter. At a predetermined instant, preferably just before the clock counter value equals to the future value, the future value is clocked into the newly installed circuit so as to synchronize the clock counter value in the new circuit to the clock counter values in the previously activated circuits.

### FIELD OF THE INVENTION

The present invention relates to a method and apparatus for providing near hit-less protection switching of cable modem data flows between active and spare cable interface cards in a cable modem termination system. In particular, the invention describes techniques that prevent cable modems from going through a time-consuming and service-affecting re-initialization process (re-ranging and re-registering) whenever a protection switch is initiated.

### BACKGROUND OF THE INVENTION

In order to provide more products and services to their subscriber base, cable television service providers are offering Internet access to subscribers through cable modem (CM) boxes. The benefits of using the cable companies instead of a dial-up Internet Service Providers include multiple services under one bill, always-on access, and, in some cases, higher speed access.

In order to provide their customers with Internet access, the cable companies use some of the 50-800 MHZ spectrum typically set aside for their television channels to provide the bandwidth required for the data transfers. A typical cable system has the bandwidth to provide 100 television channels to its subscribers. Each NTSC television signal requires 6 MHZ of bandwidth.

In order for a cable subscriber to access the Internet through their cable television provider, the subscriber must have a cable mode (CM). The CM is similar to the Cable Modem Termination System (CMTS) equipment required at the cable company's headquarters, except for the greater size required at the headquarters. This larger size is required to accommodate a greater number of channels than is required by the home CM.

The home CM box and the CMTS use well-known Ethernet frames to communicate between themselves. The cable system, however, uses a different modulation scheme, Quadrature Amplitude Modulation (QAM), than is normally used in an Ethernet scheme.

Using the QAM modulation, the downstream (from the cable company equipment to the home CM) data rate is typically in the range of 30-40 Mbps for each 6 MHZ channel. This can accommodate between 500 and 2000 subscribers. The more subscribers that the cable company tries to fit in that spectrum, the lower the bandwidth available for each of the individual subscribers.

The upstream data flow is different and more complex than the downstream data flow. In the past, cable companies did not have to worry about providing bandwidth for the customer to communicate in the upstream direction. Pay-for-view movies and sports events, however, required this ability. The cable companies therefore set aside the 5-42 MHZ spectrum to provide the necessary upstream access to the Internet from the home set-top box. This same 5-42 MHz spectrum is also used to transmit Ethernet frames from the CMs to the CMTS.

The world is now on the verge of a revolution that promises to change the way the Internet works, and will likely change the way the entire world communicates, works, and plays. The revolution is the introduction of Quality of Service (QoS) to the Internet. This QoS revolution is already beginning, because most computer networking products (switches and routers) have already added some type of QoS feature to the feature sets offered. Unfortunately, there are many different forms of QoS from which to choose and they are not all compatible with one another. Different standards committees (DiffServ, RSVP, MPLS, etc.) are still deciding which of many different QoS proposals will actually be used in the Internet, and hybrid solutions will likely be developed in the very near future that will enable the QoS revolution.

The change is important, because it will eliminate the current Internet routing model that provides the same best-effort service to all users, all packets, and all traffic flows. When QoS is enabled in a ubiquitous, end-to-end fashion across the Internet, differentiated services will be permitted, and all packets will be treated differently. High priority packets will be routed with lower latency and lower jitter, while low priority packets may experience more delay and jitter. The throughput needs of each application will determine the priority associated with its corresponding traffic flows, and it is likely that advanced application programs of the future will dynamically change the priority of traffic flows to match the very needs of the user through the entire duration of the session.

Since all packets will not be passed using the same priority level, it follows that all packets cannot be billed using the same charges in the future either. Future Internet users are likely to pay differently for different classes of service, and they may even be billed on a usage basis, e.g., per-minute, per packet, or per byte, similar to the billing schemes used for long distance telephone service today. The use of high priority traffic flow for an application will undoubtedly result in higher Internet usage costs than the use of low priority traffic flows and service level agreements (SLAs) between the Internet user and their service provider will detail the available priority and throughputs in and their associated costs. These changes in the Internet billing model represent an enhanced revenue generating potential for access providers that can provide and bill for these new differentiated services, and multiple system operators (MSOs) are key members of this group.

MSOs are positioned in an ideal location within the Internet to play a major role in the QoS revolution, and they will be able to capitalize on the resulting changes. This is because the MSOs are positioned to act as the QoS gatekeeper into the future Internet. They can perform this function because they have access to each subscriber's service level contract and can appropriately mark the priority of all packets that are injected into the Internet by their subscribers. In fact, the MSOs head end equipment, the cable modem termination system CMTS is actually the first piece of trusted equipment not owned by the subscriber to which subscriber packets must pass on their way to the Internet. The CMTS is positioned at the head end office and it provides basic connectivity between the cable plant and the Internet. FIG. 1 illustrates a simplified representation of a prior art cable data system 100 with a CMTS 102. The CMTS 102 is connected through Internet link 106 to the Internet 101. The CMTS 102 is also connected through various cable links 103 to a plurality of subscribers 104. Each of the subscribers is connected to the cable link through a cable modem 105.

The MSO also provides customer subscription packages and is able to offer (and bill for) many different subscriber service levels. In addition, if the CMTS equipment permits it, the MSO will also be able to offer dynamic service level upgrades to its subscribers. Features contained within an MSOs CMTS must provide most of these revenue generating QoS capabilities. This will result in even greater increases in revenues if the MSOs can maintain adequate counts on usage of different services levels consumed by its subscribers.

As set forth above, this CMTS provides basic connectivity between the cable plant and the local area network that interfaces to an edge router on the Internet. The CMTS is responsible for appropriately classifying, prioritizing, flow controlling, queuing, scheduling and shaping all the traffic flows between cable data subscribers and the Internet. As a result, this type of service experienced by the cable data subscribers will primarily be determined by the features in the CMTS core.

As the CMTS is used more and more to transport life-line services (such voice telephony traffic over IP) and other traffic streams that should not experience long-term service outages in excess of several seconds, it will become imperative that CMTS designs begin to provide high system availabilities. An important aspect of this requirement creates the need for a protection switching method and apparatus for cable modems from an active cable interface circuit card to a spare cable interface circuit card. Methods for efficiently providing this protection switch within a CMTS have already been documented in previously submitted patent applications. However, one of the problems that still must be solved is related to the fact that many cable modems will reset themselves and re-initiate the time-consuming process of ranging and registration if they are not provided with a valid stream of signals that help them determine when they are adequately connected to the CMTS. Since the re-ranging and re-registration process can be lengthy (requiring many seconds to many minutes), the goal of providing “near hit-less” protection switching without producing a lengthy interruption of customer services will require novel techniques that eliminate the re-ranging and re-registration of the cable modems that are connected to an active (but faulty) cable interface card that is being protection switched with a spare cable interface card.

### SUMMARY OF THE INVENTION

The invention provides a method and apparatus for maintaining the activity of the session between the cable modems and the CMTS when a protection switch occurs between two cable interface cards within the CMTS. Operational data of at least one active card is provided to the spare card a priori such that upon the active card's failure, the spare card already has been provided with all of the requisite data required by the spare card to assume the identity of the just-failed active card. In the case of critical timing data that is generated or calculated on each card, the method and apparatus disclosed herein includes keeping a master copy of the timing data and periodically distributing the data to cards that require the data, such as upon power up or failure. An offset is added to the master timing value, which is then made available to a card such that the delay in distributing a timer value is compensated. An alternate embodiment of the method includes downloading the operational data to the spare card upon the failure of an active card.

### BRIEF DESCRIPTION OF THE DRAWINGS

The teachings of the invention can be readily understood by considering the following detailed description in conjunction with the accompanying drawings.

FIG. 1 illustrates an exemplary prior art cable data system.

FIG. 2 illustrates a next-generation CMTS according to one embodiment of the invention.

FIGS. 3A and 3B illustrate the operational states of the protection switch within a CMTS according to one embodiment of the invention.

FIG. 4 illustrates the functional sub-systems within a cable interface card within a CMTS according to one embodiment of the invention.

FIG. 5 illustrates the flow of data used to load the Timing Counter on the cable interface card within a CMTS according to one embodiment of the invention.

FIG. 6 illustrates the flow of trigger signals used to initiate the loading of the Timing Counter on the cable interface card within a CMTS according to one embodiment of the invention.

FIG. 7 illustrates a generic switching system.

### DETAILED DESCRIPTION

According to one embodiment of the invention, several parameters (also referred to herein after as “service parameters”) must be correctly loaded into a spare cable interface card during a protection switch before the spare cable interface card can begin to operate in a fashion that will stop cable modems from dropping the cable modem-to-CMTS session and will stop re-initialization through the functions of ranging and registration.

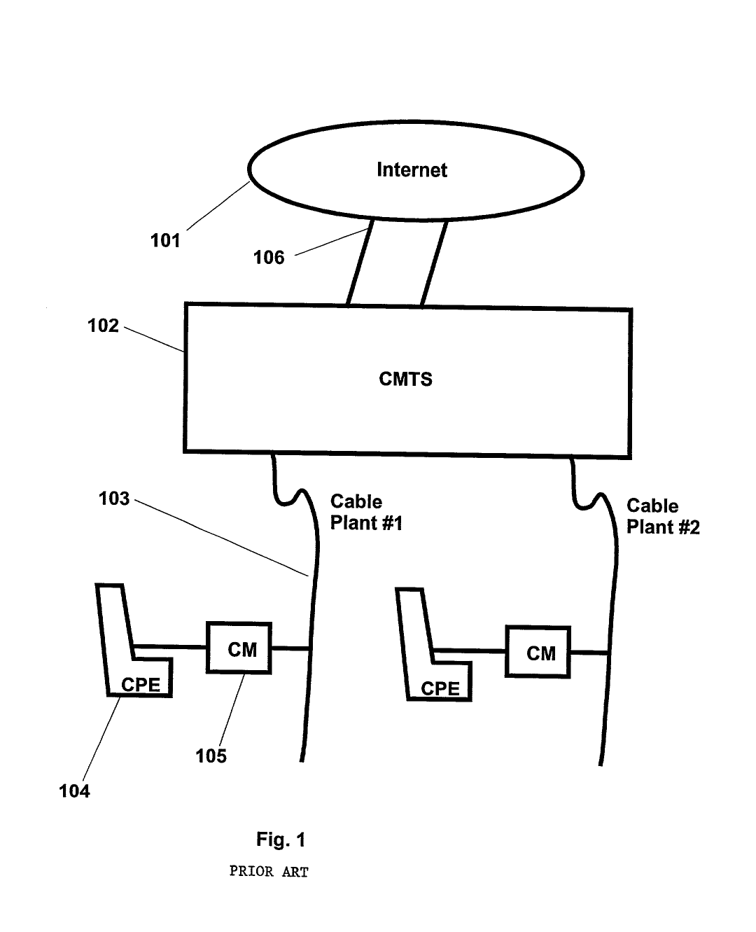

FIG. 1 illustrates a typical CMTS (102) with appropriate connections to the Internet (101) as well as with appropriate connections to subscribers through the Cable Plant (103). Various kinds of data is transferred between the Cable Modems (105) of a cable data service subscriber and the Internet by way of, or through, cable interface circuits and internet interface circuits of a typical CMTS. The equipment required at the subscriber site will typically include a Cable Modem, or CM (105) and a piece of Customer Premise Equipment, or CPE (104). The CPE can be a computer, an Internet-enabled telephone, or any other piece of equipment that can be configured as an Internet host containing an Internet Protocol address. Data from the Internet (101) is transmitted through the CMTS (102), through the CM (105), and eventually arrives at its ultimate destination at the CPE (104). Data to be sent out to the Internet is transmitted from the CPE (104) through the CM (105), through the CMTS (102), and eventually arrives at the Internet (101) which transmits it to its ultimate destination on the Internet.

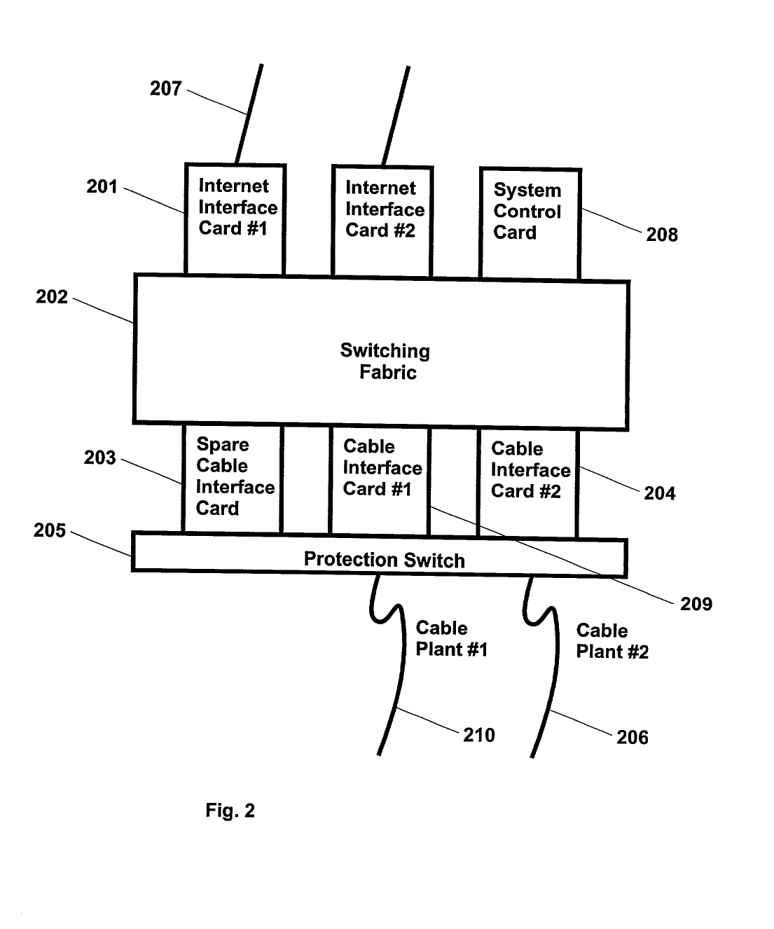

FIG. 2 illustrates the preferred embodiment cable modem termination system (CMTS) apparatus of the present invention. The CMTS apparatus of FIG. 2 is comprised of a connection to the Internet (207) that is coupled to an internet interface card (201). The internet interface card is tied to a switching fabric (202) that can forward data between any of the interfaces within the CMTS. Several cable interface cards (203, 204, and 209) will typically be clients of the switching fabric (202).

In the preferred embodiment, some of the cable interface cards (204 and 209) are directly connected to the cable plant (206 and 210) through the protection switch (205). These cable interface cards (204 and 209) are typically known as active cable interface cards because at any given instant they might be actively carrying the data between the cable plant (206 and 210) and the switching fabric (202).

In the preferred embodiment, some of the cable interface cards (203) serve as spare cable interface cards, because they are typically not directly connected to the cable plant (206 and 210) through the protection switch (205). However, if a fault is discovered on one of the active cable interface cards (such as 209), then the protection switch (205) can re-route the traffic between the switching fabric (202) and the cable plant (210) using the spare cable interface card (203) instead of the faulty cable interface card (209). The cable plant (206 and 210) is responsible for interfacing the CMTS to the home cable modem apparatus. The cable interface cards (203, 204, and 209) must therefore provide the functions of modulation and demodulation. Overall control of the CMTS system is provided by the System Control Card (208), which typically includes some sort of finite state controller such as a microprocessor and its associated software, an ASIC, a field programmable gate array or other sequential logic circuitry—not shown for purposes of clarity. The System Control Card (208) can be used to configure, manage, and diagnose faults within most of the other cards within the system.

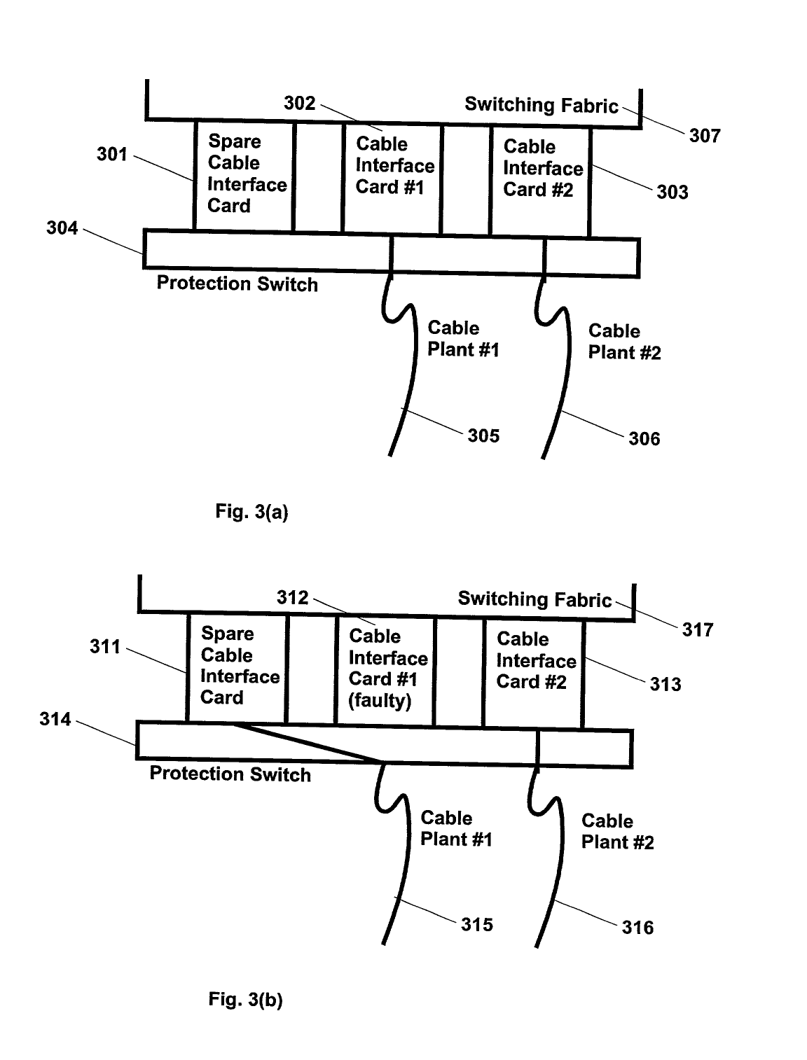

FIG. 3 illustrates the operational states of the protection switch within the CMTS. FIG. 3(a) illustrates the normal connections provided by the protection switch (304) when all of the cable interface cards (301, 302, and 303) are operating without faults within the CMTS. As a result, the active cable interface cards (302 and 303) can successfully transport the data between the switching fabric (307) and the protection switch (304) to the cable plant (305 and 306). In this non-faulty state, the spare cable interface card (301) is not required to transport any data. FIG. 3(b) illustrates the switched connections provided by the protection switch (304) when one of the cable interface cards (312) is found to be operating in a faulty mode within the CMTS. As a result, the active cable interface cards (313) can still successfully transport the data between the switching fabric (317) and the protection switch (314) to the cable plant (316). However, the faulty cable interface card (312) cannot be used. In this faulty state, the spare cable interface card (311) must be used in place of the faulty cable interface card (312). The spare cable interface card (311) is therefore required to transport the data between the switching fabric (317) and the protection switch (314) to the cable plant (315).

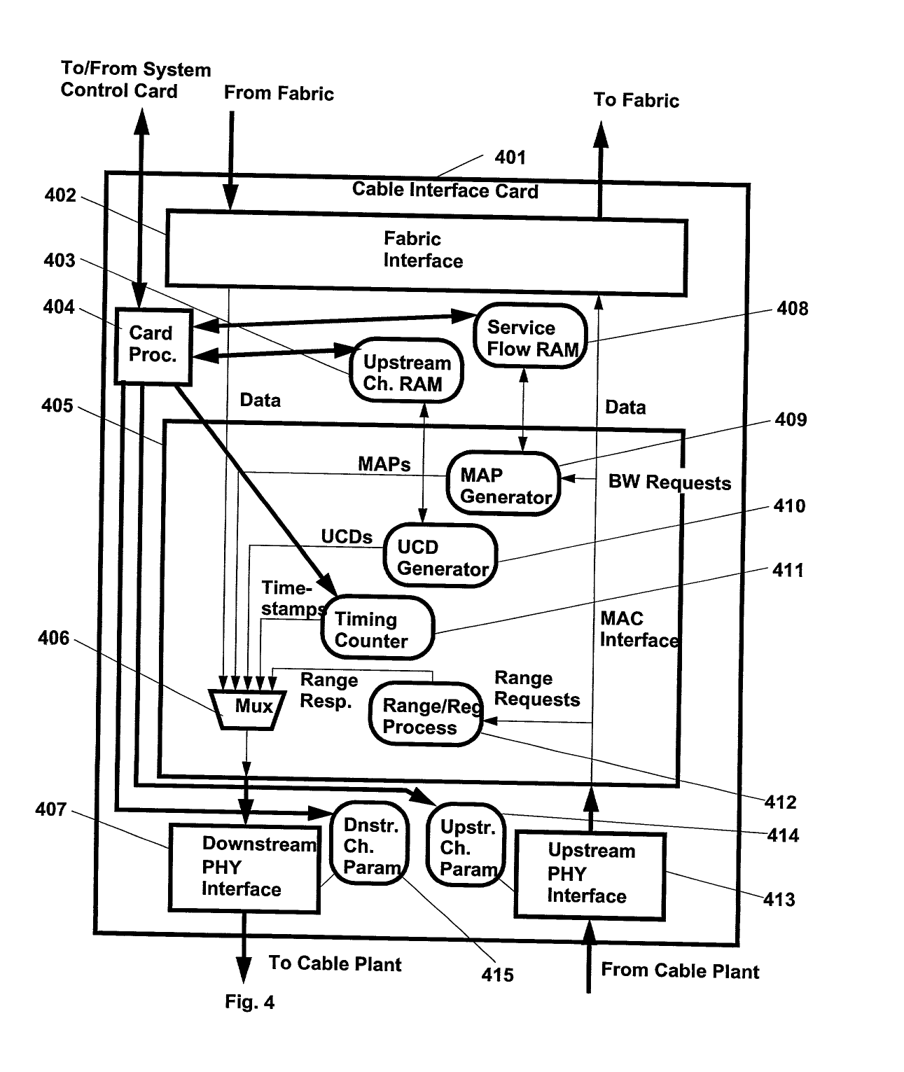

FIG. 4 illustrates the functional sub-systems in the preferred embodiment of the cable interface card (401). Basic data flow of packets from the switching fabric to the downstream cable plant passes through the fabric interface (402), through the MAC interface (405), through a mux (406), and through the downstream PHY interface (407). Basic data flow of packets from the upstream cable plant to the switching fabric passes through the upstream PHY interface (413), through the MAC interface (405), and through the fabric interface (402). The frequency information for the upstream PHY interface (413) is stored in the upstream channel parameter register (414). The frequency information for the downstream PHY interface (407) is stored in the downstream channel parameter register (415). The MAC interface (405) contains many different sub-systems. During initial session set-up for a cable modem, range request messages are transmitted in the upstream cable plant, through the upstream PHY interface (413), and on to the range/request processor (412). The range/request processor (412) sends a range response through the mux (406) and through the downstream PHY interface (407) back onto the downstream cable plant to the cable modem. The MAC interface (405) must also generate SYNC MAC Management Messages with Timing Headers (Time Stamps) specifying an appropriately advancing Global Timing Reference held in a Timing counter (411). These Time Stamps are sent through the mux (406) and through the downstream PHY interface (407) back onto the downstream cable plant to the cable modem. The MAC interface (405) must also generate the MAC Management Messages with Upstream Channel Descriptors (UCDs) specifying the upstream channels associated with the downstream channel. These UCDs are also sent through the mux (406) and through the downstream PHY interface (407) back onto the downstream cable plant to the cable modem. The UCDs are generated using the upstream channel information stored in the upstream channel RAM (403). During normal operation of a cable modem, bandwidth request messages are transmitted in the upstream cable plant, through the upstream PHY interface (413), and on to the MAP generator (409). The MAP generator (409) sends a bandwidth grant within a MAP through the mux (406) and through the downstream PHY interface (407) back onto the downstream cable plant to the cable modem, which can then transmit data packets up the cable plant in response to the grant in the MAP. The MAP grants are generated using the service flow information stored in the service flow RAM (408). All of the variables stored on the cable interface card (401) are loaded by the card processor (404) which receives its information from a data bus connecting it to the System Control Card within the CMTS.

Whenever a protection switch is initiated that switches traffic flow from a faulty cable interface card to a spare cable interface card, one problem that can occur results from the fact that the source of the signals that are generated by the cable interface card is switched, and there can be a temporary cessation or interruption or discontinuity in the flow of these signals that can cause the cable modems on the cable plant to re-initialize. This re-initialization process includes the time-consuming functions of cable modem ranging and registration, which can cause existing cable modem-to-CMTS sessions to be interrupted for an undesirably long period of time. A cessation, interruption, or discontinuity in any of the signals generated in FIG. 4 (such as downstream carrier signals from the PHY with MPEG frames, Time-stamps, UCDs, and MAPs) can cause this fundamental problem to manifest itself.

The solution to the problem requires that the spare cable interface card that is being switched into the path of the signals should produce a consistent flow of signals to the downstream cable modems that are identical to, or at least very similar to the flow of signals that were being produced by the faulty cable interface card, just prior to its failure and which is being switched, or about to be switched out of the path of the signals, and functionally replaced by a different card. In an ideal embodiment, the spare cable interface card will start producing these signals on the cable plant immediately, or almost immediately after the faulty cable interface card fails or stops sending its signals onto the cable plant. As a result, the cable modems perceive no interruption of signal flow. In a practical embodiment, the spare cable interface card will actually start producing these signals on the cable plant after a short period of time has passed after the faulty cable interface card stopped sending its signals. It is preferred that the period of time while signal flow is interrupted be short enough so that cable modems do not re-initialize. Inasmuch as nothing occurs in zero time, this nonzero period of time producing signal interruption is unavoidable due to the protection switch action and due to the required loading of appropriate information into the spare cable interface card to permit the generation of consistent signals.

Information that must be loaded into the spare cable interface card includes upstream channel parameters for the upstream PHY, downstream channel parameters for the downstream PHY (with up-converter capabilities), upstream channel information for UCD generation, service flow information for MAP generation, and the current timing counter value used for Time-Stamps. For purposes of claim construction, the foregoing informational items are identified under the designation of “parameters” and “service parameters” in that they establish (or enable) service for the modems coupled to a cable interface card.

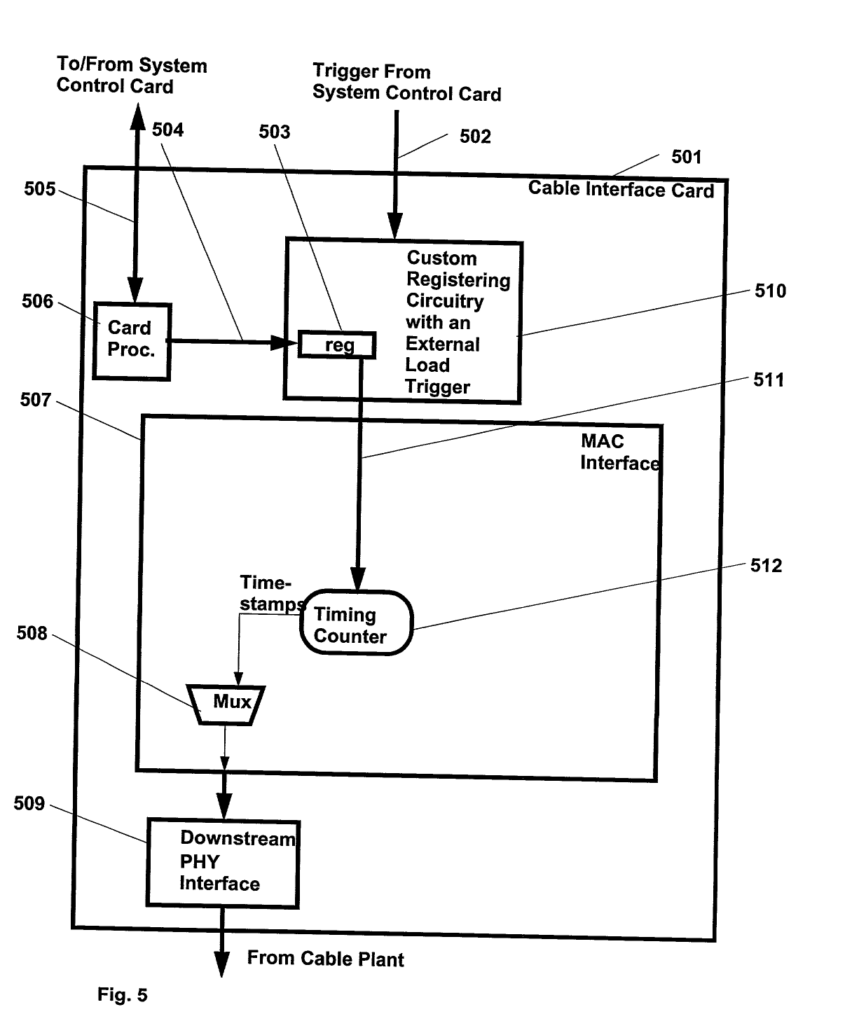

Most of these values are relatively static, and they can be rapidly loaded into the spare cable interface card's memories if copies of the values originally stored on the faulty cable interface card are also stored on the spare cable interface card. However, one of the values is changing dynamically and is quite difficult to match between the faulty cable interface card and the spare cable interface card. That value is the current timing counter (identified by reference numeral 411 in FIG. 4 and by 512 in FIG. 5) value used for Time-Stamps. In the preferred embodiment, the current timing counter value is a 32-bit binary counter that is clocked with a 10.24 MHz master clock (once every 97.7 nsec). Every cable interface card will typically contain one of these current timing counters since they are usually contained in silicon within the MAC Interface chip. If the switch-over from a faulty cable interface card to a spare cable interface card is to produce an uninterrupted sequence of Time-Stamps, then the current timing counter values on both the faulty cable interface card and spare cable interface card need to be synchronized values. This requires that both counters be initially loaded with the same value. Unfortunately, not all of the counters will always be initially loaded at the same point in time since different cable interface cards are likely to be inserted into the chassis at different moments in time. Cards might be replaced, deliberately or inadvertently, power can be interrupted, any occurrence of which would necessitate updating the timer counter value in a spare card (or active card) so as to maintain timer counter value synchronization between all cards. Unfortunately, this leads to complications.

A preferred solution to the problem of timer counter value synchronization is to have the CMTS maintain a master timing counter running on the System Controller card, and it must also have a slave timing counter running on each of the cable interface cards in the CMTS. Ideally, all of these timing counters would be clocked from the same distributed clock signal, so all of the timing counters should increment at the same rate. Although it is not shown, in the embodiments depicted in the figures, there is distributed to all of the synchronous circuitry, a master clock signal which provides among other things, assurance that the timer counters in the various interface cards increment in synchronism with each other. Thus, if the value in the master timing counter is at least periodically distributed to the cable interface cards and that value is loaded into the slave timing counters, then all of the timing counters that receive the same master clock signal should remain synchronized so that a protection switch will not cause undesirable jumps or discontinuities in the Time Stamp values used between the faulty cable interface card and the spare cable interface card. To maintain synchronization, the periodic distribution of the master timing counter value to all of the slave timing counters should be initiated on a periodic basis, and it should also be initiated whenever a cable interface card is inserted or initialized.

The difficult task in the clock count/timer value distributions ensuring that the timing counters on all circuit cards load up the same value at substantially the same moment in time whenever a distribution occurs. In addition, any actively incrementing timing counters that are already being used to transmit Time Stamp values to cable modems should be loaded with a value that is either identical to or “very close” to the value that is stored in the master timing counter at the time when the clock count/timer value loading into a timer counter actually takes place. According to the Data-Over-Cable Service Interface Specifications (Radio Frequency Interface Specification SP-RFIv1.I04-000407) published by Cable Television Laboratories, Inc., two successively transmitted Time Stamp values (N1 and N2) that are transmitted at times T1 and T2 must have values that satisfy the jitter requirement:

|(N2−N1)/10240000−(T2−T1)|<500 nsec.

This jitter requirement assumes that the timing counters are being clocked with a 10.24 MHz clock, and it must be satisfied even if Time Stamp value N1 is transmitted from the faulty cable interface card and Time Stamp value N2 is transmitted from the spare cable interface card (after the protection switch is thrown).

In the preferred embodiment the System Controller card samples the current state of the master timing counter (which is on the System Controller card) and store this value. With respect to FIG. 5, when some other card requires its timer counter value to be synchronized, the System Controller can download the stored value via the bus 504 to a local card controller 506. In theory, the local controller 506 can load the master timing counter value into a register 503 which can clock the stored value directly into the timing counter 512. Inasmuch as the timing counters all receive the same system clock signal, all of the timing counters 512 on other cards should increment in lock step thereafter. In reality however, loading the master timing counter value into the timing controller takes so much time that by the time the master timing counter value was written into the new timing counter, the real value of the master timing counter will have changed. Accordingly, the preferred methodology for updating a timing counter adds to the master timing controller value, a positive offset amount, which is loaded into the register 503 for a subsequent control signal from either the local card processor 506 or in some embodiments the System Controller. By adding a positive offset to the master timing counter and saving this value as the new value loaded into the timing controller, the resultant value can be locally clocked into the timing counter 512 by a trigger control signal 502 from the System Controller when the System Controller determines that the next value of the master timing controller will be equal the stored value in the register 503. In other words, the System Controller card increases the sampled count value by a pre-determined amount in order to transform the sampled count value into a new increased value (pointing at a point in time in the future) so as to compensate for the time required to transfer the new increased value into a local register 503 from which it can be clocked under the System Controller 502 into the local timing counter 512. The increased count value should be created such that the actual loading of this increased count value into the slave timing counters (after distribution from the System Controller card to the cable interface cards) will occur exactly when the master timing counter on the System Controller card arrives at the value which is equal to the increased value. This will keep the master timing counter and all slave timing counters in synchronization.

The novel hardware arrangement needed within a CMTS to provide the aforementioned solution is illustrated in FIG. 5. FIG. 5 illustrates the necessary elements needed to implement the solution in the preferred embodiment of the cable interface card (501). The increased count value described in the solution is distributed from the System Controller card to the cable interface card (501) over the processor communication bus (505). Upon arriving at the cable interface card (501), the increased count value is stored in the Card Processor complex (506). The Card Processor complex (506) can then write the increased count value over an intra-card processor bus (504) into a storage register (503) within an on-board FPGA or ASIC (510). The FPGA or ASIC (510) is connected to the MAC Interface chip (507) through an intra-chip bus (511). The actual timing counter (512) within the MAC Interface chip (507) can be directly loaded through the intra-chip bus (511). This loading only occurs when the Trigger signal (502) is asserted by the System Controller card. If all the storage registers (503) on all cable interface cards are loaded with the same value and then all of the Trigger signals (502) to all of the cable interface cards are asserted at the same time, then all of the actual timing counters (512) will be loaded with the same value at the same point in time. If the increased count value was calculated correctly, then the timing counter should not jump when the value is loaded into an already operating counter. Once the timing counter (512) is loaded, the timing value can be injected in the Time Stamps that are sent through the Mux (508) an then on to the Downstream PHY Interface (509) before being sent onto the cable plant.

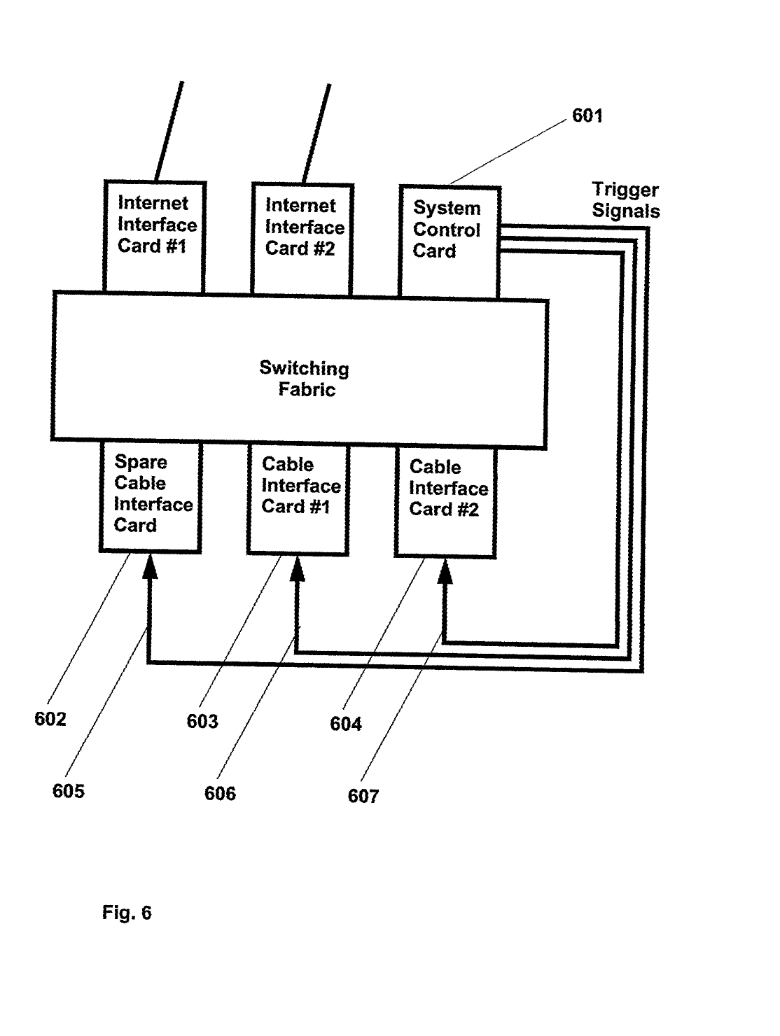

In order to correctly distribute the Trigger signals to all the cable interface cards in the system to load the timing counters in unison, a scheme similar to the one shown in FIG. 6 can be used. In FIG. 6, the System Controller card (601) drives a unique Trigger signal for each of the cable interface cards. Thus, Trigger signal (605) can be used to load spare cable interface card (602). Trigger signal (606) can be used to load cable interface card #1 (603). Trigger signal (607) can be used to load cable interface card #2 (604).

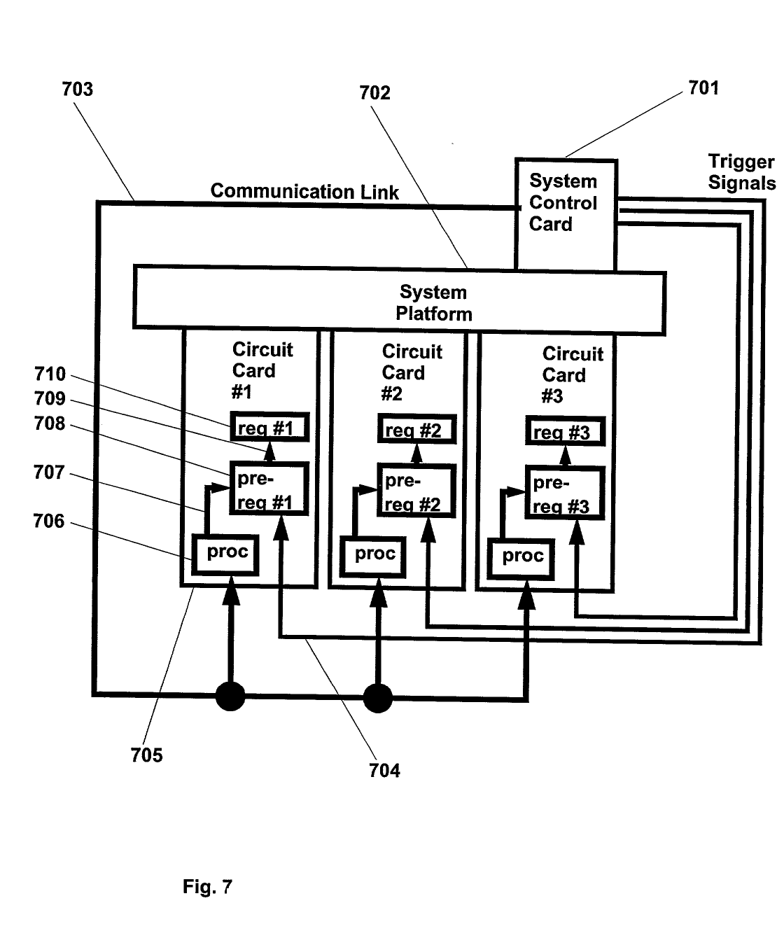

In addition to the foregoing method and apparatus for a CMTS, the method and apparatus of synchronously updating the timing counters is not limited to use for Time-stamps within a CMTS. Many different types of networking products, switching products, and test equipment products require registers that must be synchronously loaded across multiple circuit cards. For purposes of claim construction, all such systems are identified herein as “synchronous clock systems.” These registers might be used as timers, as event counters, or as storage elements for various measurements. The synchronous pre-setting of these registers can be implemented using a method and apparatus similar to the techniques described above for loading the timing counters within a CMTS. FIG. 7 illustrates such a generic system.

In FIG. 7, the System Controller card (701) distributes a desired register value to one or more of the Circuit Cards (705) over a communication link (703). The desired register value is actually written to the processor complex (706) on the desired set of Circuit Cards (705). The processor complex (706) can then inject the desired register value into the Pre-Register (708) using a bus (707) on the Circuit Card (705). At the appropriate moment in time, the System Controller card (701) can distribute Trigger Signals (704) to all of the Circuit Cards (705) that are to simultaneously load the Register (710). The actual load takes place over a bus (709) between the Pre-Register (708) and the Register (710). This approach can be valuable in many different types of electronic systems.

While exemplary systems and method embodying the present invention are shown by way of example, it will be understood, of course, that the invention is not limited to these embodiments. Modifications may be made by those skilled in the art, particularly in light of the foregoing teachings. For example, a single Trigger signal could be distributed in a multi-drop bus system to drive all of the cable interface cards in unison.

We claim:

1. In a cable modem termination system (CMTS) having at least a first active cable interface circuit transferring a first set of data signals to at least one cable modem using a first set of parameters stored within said first active cable interface circuit, said CMTS also having at least one spare interface circuit that is capable of communicating with a plurality of cable modems, a method of routing said first set of signals to said spare interface circuit comprised of the steps of:
a. copying at least a plurality of said first set of parameters for said first active cable interface circuit into said spare interface circuit;
b. on the failure of said first active cable interface circuit, routing said first set of data signals through said spare interface circuit according to said first set of parameters for said first active cable interface circuit that were copied into said spare interface circuit.

2. The method of claim 1 wherein said step of copying at least a plurality of said first set of parameters for said first active cable interface circuit into said spare interface circuit includes the step of: copying a plurality of parameter sets, for a plurality of active cable interface circuits into said spare interface circuit.

3. The method of claim 1 wherein said step of copying said first set of parameters for said first active cable interface circuit into said spare interface circuit includes the step of:
reading said first set of parameters from said first active cable interface circuit from memory comprising said first active cable interface circuit;
transferring the first set of parameters that were read from said first active cable interface into said spare interface circuit.

4. The method of claim 1 wherein said step of copying said first set of parameters for said first active cable interface circuit into said spare interface circuit includes the step of:
reading said first set of parameters from said first active cable interface circuit from a System Controller for said CMTS;
transferring the first set of parameters that were read from said System Controller for said CMTS into said spare interface circuit.

5. The method of claim 1 wherein said first set of parameters includes at least one of the following:
a. Downstream channel parameters;
b. Upstream channel parameters;
c. Service flow identification information;
d. Upstream channel identification information;
e. Upstream channel descriptor information.
f. At least one timing counter value.

6. In a cable modem termination system (CMTS) with a plurality of active cable interface circuits, each of which transfers data signals to a plurality of cable modems, each cable modem receiving said data signals through a corresponding one active cable interface circuit, the transfer of said data signals to each of said cable modems being enabled according to a set of service parameters for each cable modem of said plurality of cable modems that is stored in the cable modem's corresponding active cable interface circuit, said CMTS also having at least one spare cable interface circuit that is capable of communicating with any of said plurality of cable modems, a method of routing said data signals to at least one of said cable modems through said spare cable interface circuit comprised of the steps of:
copying said service parameters of said first active cable interface circuit into said spare cable interface circuit;
on the failure of a first active cable interface circuit, routing data signals destined for said at least one cable modem through said spare cable interface circuit according to said first set of parameters for said first active cable interface copied into said spare cable interface circuit.

7. The method of claim 6 wherein said step of copying said service parameters of said first active cable interface circuit into said spare cable interface circuit includes the step of: copying a plurality of service parameter sets, for a plurality of active cable interface circuits into said spare cable interface circuit.

8. The method of claim 6 wherein said step of copying said service parameters for said first active cable interface circuit into said spare cable interface circuit includes the step of:
reading said service parameters for said active cable interface circuit from memory comprising said first active cable interface circuit;
transferring the service parameters t hat were read from said first active cable interface in to said spare cable interface circuit.

9. The method of claim 6 wherein said step of copying said first set of parameters for said first active cable interface circuit into said spare cable interface circuit includes the step of:
reading said service parameters from said first active cable interface circuit from a System Controller for said CMTS;
transferring the service parameters that were read from said System Controller for said CMTS into said spare cable interface circuit.

10. The method of claim 6 wherein said service parameters includes at least one of the following:
g. Downstream channel parameters;
h. Upstream channel parameters;
i. Service flow identification information;
j. Upstream channel identification information;
k. Upstream channel descriptor information.
l. At least one timing counter value.

11. In a cable modem termination system (CMTS) with a plurality of cable interface circuits, each of which includes a cyclical timing counter that provides timing signals to cable modems coupled to each of said interface circuits, a method of synchronizing the timing counter of a first cable interface circuit to the timing counter of a second cable interface circuit comprised of the steps of:
copying a first value of said timing counter of said first cable interface circuit into a storage device;
adding an offset to said first value to create a future timing counter value;
copying said future timing counter value into a storage device;
copying said future timing counter value from said storage device into said timing counter.

12. The method of claim 11 wherein said step of copying said future ting counter value from said storage device into said timing counter includes the step of:
a. waiting a predetermined length of time until said timing counter is substantially equal to said future timing counter value;
b. copying said future timing counter value from said storage device into said timing counter.

13. The method of claim 11 wherein said step of copying said future timing counter value from said storage device into said timing counter includes the steps of:
c. waiting a predetermined length of time until said timing counter increases to a value substantially equal to said future timing counter value;
d. copying said future timing counter value from said storage device into said timing counter.

14. The method of claim 11 wherein said step of copying said future timing counter value from said storage device into said timing counter includes the step of:
e. triggering the transfer of said future timing counter value from said storage device into said timing counter from a System Controller for said CMTS.

15. A cable modem termination system (CMTS) with a plurality of interface circuits, each of which includes a cyclical timing counter that provides timing signals to cable modems coupled to each of said interface circuits, said CMTS comprising:
a System Controller means for: copying a first value of said timing counter of said first cable interface circuit into a storage device; adding an offset to said first value to create a future timing counter value; copying said future timing counter value from said storage device into said timing counter.

16. The CMTS of claim 15 wherein said System Controller means is a microprocessor.

17. The CMTS of claim 15 wherein said System Controller means is an application specific integrated circuit

18. The CMTS of claim 15 wherein said System Controller means is a field programmable gate array (FPGA).

19. The CMTS of claim 15 wherein said System Controller means is sequential logic.

20. In a synchronous clock system with a plurality of circuit cards, each of which includes a timing counter that provides timing signals, a method of synchronizing the timing counter of a first circuit card to the timing counter of a second circuit card comprised of the steps of:
copying a first value of said timing counter of said first circuit card into a storage device;
adding an offset to said first value to create a future timing counter value;
copying said future timing counter value from said storage device into said timing counter of said second card.

21. The method of claim 20 wherein said step of copying said future timing counter value from said storage device into said timing counter includes the steps of:
a. waiting a predetermined length of time until said timing counter of said first circuit card is substantially equal to said future timing counter value;
b. copying said future timing counter value from said storage device into said timing counter of said second card.

22. The method of claim 20 wherein said step of copying said future timing counter value from said storage device into said timing counter of said second card includes the steps of:
c. waiting a predetermined length of time until said timing counter increases to a value substantially equal to said future timing counter value;
d. copying said future timing counter value from said storage device into said timing counter of said second card.

23. The method of claim 20 wherein said step of copying said future timing counter value from said storage device into said timing counter of said second card includes the step of:
e. triggering the transfer of said future timing counter value from said storage device into said timing counter from a System Controller for said synchronous clock system.

24. A synchronous clock system having a plurality of circuit cards, each of which includes a cyclical timing counter that provides timing signals to cable modems coupled to each of said interface circuits, said synchronous clock system comprising:
a System controller means for: copying a first value of said timing counter of said first circuit card into a storage device; adding an offset to said first value to create a future timing counter value; and copying said future timing counter value into a storage device for a second circuit card.

25. The synchronous clock system of claim 24 wherein said System Controller means is a microprocessor.

26. The synchronous clock system of claim 24 wherein said System Controller means is an application specific integrated circuit

27. The synchronous clock system of claim 24 wherein said System Controller means is a field programmable gate array (FPGA).

28. The synchronous clock system of claim 24 wherein said System Controller means is sequential logic.
